(19) United States
(12) Patent Application Publication
(10) Pub. No.: US 2025/0269732 A1
(43) Pub. Date: Aug. 28, 2025

(54) ELECTRONIC SYSTEM INCLUDING CENTRAL CONTROLLER AND ZONAL CONTROLLER AND VEHICLE INCLUDING THE SAME

(71) Applicant: Samsung Electronics Co., Ltd., Suwon-si (KR)

(72) Inventor: Seungcheol LEE, Suwon-si (KR)

(73) Assignee: Samsung Electronics Co., Ltd., Suwon-si (KR)

(21) Appl. No.: 18/779,155

(22) Filed: Jul. 22, 2024

(30) Foreign Application Priority Data
Feb. 27, 2024 (KR) 10-2024-0028262

(51) Int. Cl. B60L 15/20; B60L 15/08

(52) U.S. Cl. CPC B60L 15/20; B60L 15/08; B60L 2240/12

(57) ABSTRACT

An electronic system may include a central controller configured to, receive speed information related to a current speed of a vehicle, generate target speed information representing a speed at which the vehicle will travel based on the speed information, and transmit the target speed information, and a first zonal controller configured to control a first zone among a plurality of zones of the vehicle, and a second zonal controller configured to control a second zone among the plurality of zones of the vehicle, and control at least one motor of the vehicle based on the target speed information received from the central controller, the at least one motor configured to drive at least one wheel of the vehicle.

### CROSS-REFERENCE TO RELATED APPLICATION

This U.S. non-provisional application claims the benefit of priority to Korean Patent Application No. 10-2024-0028262 filed in the Korean Intellectual Property Office on Feb. 27, 2024, the entire contents of which is incorporated herein by reference.

### BACKGROUND

Various example embodiments of the inventive concepts relate to an electronic system including a central controller and a zonal controller, a vehicle including the same, and/or methods for operating the electronic system, etc.

The electronic system of a conventional vehicle is a system in which the controllers that control the powertrain, chassis, body, in-vehicle infotainment (IVI), and/or advanced driver assistance system (ADAS) are distributed. Currently, the electronic system of a vehicle is changing to a centralized electronic system in which the multiple zones of the vehicle are controlled by multiple zone controllers, and the multiple zone controllers are controlled by a central controller capable of high-performance computing.

### SUMMARY

Various example embodiments of the inventive concepts provide an electronic system including a central controller and a zonal controller, a vehicle including the same, and/or a method of operating the electronic system, etc., capable improving performance for controlling the vehicle in the longitudinal direction.

An electronic system may include a central controller configured to, receive speed information related to a current speed of a vehicle, generate a target speed information representing a speed at which the vehicle will travel based on the speed information, and transmit the target speed information, and a first zonal controller configured to control a first zone among a plurality of zones of the vehicle, and a second zonal controller configured to control a second zone among a plurality of zones of the vehicle, and control at least one motor of the vehicle based on the target speed information received from the central controller, the at least one motor configured to drive at least one wheel of the vehicle.

An electronic system may include an inverter configured to convert a voltage of a battery to a driving voltage, at least one motor configured to operate based on the driving voltage, a plurality of zonal controllers configured to control each of a plurality of zones of the vehicle, and a central controller configured to determine target speed information based on current rotation speed information of the at least one motor and desired speed information of a vehicle housing the at least one motor, the target speed information indicating a target speed at which the vehicle will travel, and the desired speed information indicating a desired speed to which the vehicle will increase or decrease. Wherein one zonal controller for controlling one of the plurality of zones of the vehicle is configured to receive the target speed, and adjust the driving voltage based on a target current corresponding to the target speed information and a driving current corresponding to the driving voltage.

A vehicle may include a first motor and a second motor each configured to drive at least one first wheel and at least one second wheel, respectively, a central controller configured to generate target speed information and speed change information of the vehicle, the target speed information representing a speed at which the vehicle will travel based on rotation speed information of the first motor and the second motor, a first zonal controller configured to control a first zone among a plurality of zones of the vehicle, and control a first driving voltage applied to the first motor based on the target speed information, and a second zonal controller configured to control a second zone among the plurality of zones of the vehicle, and control a second driving voltage applied to the second motor based on the target speed information.

### BRIEF DESCRIPTION OF THE DRAWINGS

FIG. 1 is a drawing illustrating an example vehicle including an electronic system according to at least one example embodiment.

FIG. 2 is a block diagram of an example electronic system including a central controller and a zonal controller according to at least one example embodiment.

FIG. 3 is a block diagram of an example central controller according to at least one example embodiment.

FIG. 4 is a block diagram of an example zonal controller according to at least one example embodiment.

FIG. 5 is a diagram of an example inverter, motor, and zonal controller according to at least one example embodiment.

FIG. 6 is a block diagram of example zonal controllers for controlling a plurality of motors according to at least one example embodiment.

FIG. 7 is a flowchart illustrating an example method of operating an electronic system according to at least one example embodiment.

FIG. 8 is a flowchart illustrating an example method of operating a zonal controller according to at least one example embodiment.

### DETAILED DESCRIPTION

Various example embodiments of the inventive concepts will be described more fully hereinafter with reference to the accompanying drawings. As those of ordinary skill in the art would realize, the described example embodiments may be modified in various different ways, all without departing from the spirit or scope of the inventive concepts.

The drawings and description are to be regarded as illustrative in nature and not restrictive, and like reference numerals designate like elements throughout the specification.

In addition, unless explicitly described to the contrary, the word “comprise” and variations such as “comprises” or “comprising”, will be understood to imply the inclusion of stated elements but not the exclusion of any other elements.

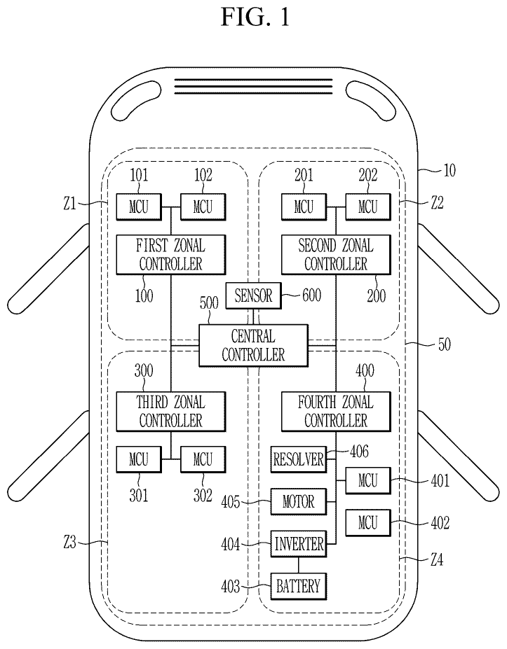

FIG. 1 is a drawing illustrating an example vehicle including an electronic system according to at least one example embodiment.

Referring to FIG. 1, a vehicle 10 may include an electronic system 50, but is not limited thereto. The electronic system 50 may be a system for processing data generated by the vehicle 10. In at least one example embodiment, the vehicle 10 may include a plurality of zones, e.g., a first zone Z1, a second zone Z2, a third zone Z3, and/or a fourth zone Z4, etc., but is not limited thereto, and for example may include a greater or lesser number of zones, etc.

The electronic system 50 may include a plurality of zonal controllers, e.g., a first zonal controller 100, a second zonal controller 200, a third zonal controller 300, a fourth zonal controller 400, etc., a central controller 500, a sensor 600, a battery 403, an inverter 404, a motor 405, a resolver 406, and/or a plurality of micro control units (MCU) 101, 102, 201, 202, 301, 302, 401, and 402, etc., but the example embodiments are not limited thereto. According to some example embodiments, one or more of the first zonal controller 100, the second zonal controller 200, a third zonal controller 300, a fourth zonal controller 400, the central controller 500, the sensor 600, and/or a plurality of micro control units (MCU) 101, 102, 201, 202, 301, 302, 401, 402, etc., may be implemented as processing circuitry. Processing circuitry may include hardware or hardware circuit including logic circuits; a hardware/software combination such as a processor executing software and/or firmware; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc., but is not limited thereto.

The plurality of micro control units (MCU), e.g., MCUs 101, 102, 201, 202, 301, 302, 401, and/or 402, etc., may control operations performed in and/or by the vehicle 10 based on information obtained from the inside and/or the outside of the vehicle. For example, one or more of the plurality of micro control units (MCU) 101, 102, 201, 202, 301, 302, 401, and 402 may control the heating wire of the vehicle seat based on temperature information received from a temperature sensor within the vehicle 10, etc., but the example embodiments are not limited thereto, and the plurality of MCUs may control other features of the vehicle 10, such as steering, accelerating, braking, air conditioning, heating, displays, lighting, communication, entertainment, charging, etc.

The first zonal controller 100, the second zonal controller 200, the third zonal controller 300, and/or the fourth zonal controller 400 may control one or more of the plurality of micro control units (MCU) 101, 102, 201, 202, 301, 302, 401, and/or 402, etc.

In at least one example embodiment, the first zonal controller 100, the second zonal controller 200, the third zonal controller 300, and the fourth zonal controller 400 may control the operations performed by vehicle equipment associated with and/or corresponding to the first zone Z1, the second zone Z2, the third zone Z3, and the fourth zone Z4, respectively, but are not limited thereto. According to some example embodiments, the zonal controllers may be dedicated controllers for performing a subset of tasks and/or managing a subset of equipment of the vehicle 10, and accordingly, the zonal controllers may have less processing power, less memory resources, etc., than the central controller 500 thereby reducing the costs of the electronic system 50, but the example embodiments are not limited thereto, and for example the zonal controllers may have the same and/or greater processing power and/or memory resources than the central controller 500, etc. Further, because the control of individual sub-systems of the vehicle 10 may be performed by multiple zonal controllers based on inputs from the central controller 500, the transmission speed and/or latency of transmitting instructions and/or commands may be reduced, and the probability of instructions and/or commands not being received by vehicle equipment and/or sub-systems is reduced in comparison to having the central controller 500 control all of the vehicle equipment, thereby improving the functionality and/or safety of the vehicle 10.

In at least one example embodiment, the first zonal controller 100 may control operation performed in the first zone Z1. For example, the first zone Z1 may be an area corresponding to front left side of the vehicle 10, but is not limited thereto, and for example the first zone Z1 may refer to at least one component and/or sub-system of the vehicle 10, such as the heating and air conditioning (HVAC) subsystem of the vehicle 10, the driving subsystem of the vehicle 10, the entertainment subsystem of the vehicle 10, etc. The first zonal controller 100 may receive data from MCUs 101 and 102, and may control operation of the MCUs 101 and 102, etc. For example, the first zonal controller 100 may control the MCUs 101 and 102 to increase or decrease the temperature of a front left seat based on temperature information received from the temperature sensor within the vehicle 10, etc.

In at least one example embodiment, the second zonal controller 200 may control operation performed in the second zone Z2. For example, the second zone Z2 may be an area corresponding to front right side of the vehicle 10, but is not limited thereto, and for example the second zone Z2 may refer to at least one component and/or sub-system of the vehicle 10, etc. The second zonal controller 200 may receive data from MCUs 201 and 202, and may control operation of the MCUs 201 and 202, etc. For example, the second zonal controller 200 may control the MCUs 201 and 202 to increase or decrease the temperature of a front right seat based on temperature information received from the temperature sensor within the vehicle 10, etc.

In at least one example embodiment, the third zonal controller 300 may control operation performed in the third zone Z3. For example, the third zone Z3 may be an area corresponding to rear left side of the vehicle 10, but is not limited thereto, and for example the third zone Z3 may refer to at least one component and/or sub-system of the vehicle 10, etc. The third zonal controller 300 may receive data from MCUs 301 and 302, and may control operation of the MCUs 301 and 302, etc. For example, the third zonal controller 300 may control the MCUs 301 and 302 to increase or decrease the temperature of a rear left seat based on temperature information received from the temperature sensor within the vehicle 10, etc.

In at least one example embodiment, the fourth zonal controller 400 may control operation performed in the fourth zone Z4. For example, the fourth zone Z4 may be an area corresponding to rear right side of the vehicle 10, but is not limited thereto, and for example the fourth zone Z4 may refer to at least one component and/or sub-system of the vehicle 10, etc. The fourth zonal controller 400 may receive data from MCUs 401 and 402, and may control operation of the MCUs 401 and 402, etc. For example, the fourth zonal controller 400 may control the MCUs 401 and 402 to increase or decrease the temperature of a rear right seat based on temperature information received from the temperature sensor within the vehicle 10, etc. However, the example embodiments are not limited to the at least one example embodiment illustrated in FIG. 1, and for example, the vehicle 10 may include a greater or lesser number of zones, a greater or lesser number of zonal controllers, and/or a greater or lesser number of MCUs, etc.

The battery 403 may store electrical energy used to operate and/or drive the vehicle 10. In at least one example embodiment, the battery 403 may supply a direct current (DC) power.

The inverter 404 may convert the voltage of the battery 403 to a driving voltage, and may apply the driving voltage to the motor 405. In at least one example embodiment, the inverter 404 may convert DC power of the battery 403 to the driving voltage corresponding to alternating current (AC) power.

According to at least one example embodiment, the at least one motor 405 may be an electric motor for a battery electric vehicle (BEV) and/or a hybrid electric vehicle (e.g., a vehicle with an electric motor and an internal combustion engine) and may operate and/or drive the vehicle 10 based on the driving voltage applied and/or received from the inverter 404, but the example embodiments are not limited thereto, and for example, the motor 405 may be an internal combustion engine for a gasoline and/or diesel powered vehicle, a hybrid electric vehicle, etc. In the example embodiments where the motor 405 is an internal combustion engine, the driving voltage may be a control signal for a throttle control system (e.g., drive-by-wire throttle system, etc.) for the internal combustion engine, etc., but is not limited thereto. In at least one example embodiment, the motor 405 may perform rotational movement according to and/or based on the driving voltage, and the vehicle 10 may be driven as at least one wheel connected to the motor 405 is rotated by the motor 405. In at least one example embodiment, the at least one wheel connected to the motor 405 may be located in the rear of the vehicle. In at least one other example embodiment, the at least one wheel connected to the motor 405 may be located in the front of the vehicle. In some example embodiments, the motor 405 may be a plurality of motors each connected to one or wheels of the vehicle 10, but the example embodiments are not limited thereto.

The resolver 406 may detect a rotor position of a rotor and/or shaft rotating in the motor 405. The resolver 406 may provide information on the rotor position (e.g., an angle and/or displacement speed, etc.) to a zonal controller controlling the motor 405, but is not limited thereto. Additionally, or alternatively, an encoder, etc., may be used to detect the rotor position information of the motor 405.

The central controller 500 may control overall operation of the electronic system 50. In at least one example embodiment, the central controller 500 may control the operation of the first zonal controller 100, the second zonal controller 200, the third zonal controller 300, and/or the fourth zonal controller 400, etc. In at least one example embodiment, the central controller 500 may communicate data with the first zonal controller 100, the second zonal controller 200, the third zonal controller 300, and/or the fourth zonal controller 400, etc., through at least one communications bus, such as an Ethernet network bus, but the example embodiments are not limited thereto, and for example, other communication protocols and/or interfaces may be implemented.

In at least one example embodiment, the central controller 500 may process data related to an advanced driver assistance system (ADAS), but is not limited thereto. In at least one example embodiment, ADAS may include one or more functions, such as lane departure warning (LDW), lane keeping assist (LKA), high beam assist (HBA), autonomous emergency braking (AEB), traffic sign recognition (TSR), smart cruise control (SCC), blind spot detection (BSD), and/or forward collision-avoidance assist (FCA), etc., but is not limited thereto.

In at least one example embodiment, the central controller 500 may process data related to in-vehicle infotainment (IVI), etc. For example, the central controller 500 may control audio and/or video information related to vehicle settings (e.g., heating and/or cooling settings, seat settings, lighting settings, driving settings, etc.), navigation functions, communication functions (e.g., phone calls, emails, text messages, etc.), entertainment (e.g., music, movies, TV, games, etc.), etc., to be output through at least one display in the vehicle 10.

In at least one example embodiment, the central controller 500 may receive speed information related to a speed of the vehicle 10, and may generate target speed information representing a desired speed at which the vehicle 10 will travel based on the speed information, etc. In at least one example embodiment, the speed information may include travel speed information representing a current speed of the traveling vehicle 10, speed change information representing a speed to which the vehicle 10 will increase or decrease, gear information representing a gear position of the transmission, and/or rotation speed information representing a speed at which the motor 405 rotates, etc., but is not limited thereto.

In at least one example embodiment, the central controller 500 may receive the travel speed information, the speed change information, and/or the gear information, etc., from the at least one sensor 600. In at least one example embodiment, the central controller 500 may receive the rotation speed information from the zonal controller controlling the motor 405 among first to fourth zonal controllers 100, 200, 300, and/or 400, etc. In at least one example embodiment, the central controller 500 may provide the target speed information to the zonal controller controlling the motor 405, etc.

The at least one sensor 600 may detect the current speed of the traveling vehicle, a level of depressing the pedal(s) by a driver driving and/or operating the vehicle, the current revolutions per minute (RPMs) of the motor 405, and/or the position of the transmission, etc. The sensor 600 may generate the travel speed information based on the current speed of the traveling vehicle, etc. The sensor 600 may generate the speed change information based on the level of depressing the pedal(s) by the driver. The sensor 600 may generate the gear information based on the position of the transmission. The sensor 600 may provide the travel speed information, the speed change information, and/or the gear information, etc., to the central controller 500. In at least one example embodiment, the sensor 600 may be located in the first zone Z1 where the driver is seated, but is not limited thereto. For example, the sensor 600 may include an accelerator pedal sensor, a brake pedal sensor, a clutch pedal sensor, a transmission selection sensor, or the like, that may be manipulated by the driver. The sensor 600 may be connected to the first zonal controller 100, etc. The information pieces generated from the sensor 600 may be provided to the central controller 500 through the first zonal controller 100, but is not limited thereto.

In at least one example embodiment, one zonal controller among the first zonal controller 100, the second zonal controller 200, the third zonal controller 300, and the fourth zonal controller 400, etc., may control the motor 405 configured to drive the vehicle 10, but the example embodiments are not limited thereto. In FIG. 1, it is assumed, for the sake of clarity and brevity, that the fourth zonal controller 400 controls the motor 405, but the example embodiments are not limited thereto.

In at least one example embodiment, the fourth zonal controller 400 may receive the target speed information from the central controller 500. The fourth zonal controller 400 may control the motor 405 configured to drive the vehicle 10 based on the target speed information. In at least one example embodiment, the fourth zonal controller 400 may generate a pulse width modulation (PWM) signal that controls a width of the driving voltage to be applied to the motor 405 based on the target speed information. In at least one example embodiment, the fourth zonal controller 400 may control the inverter 404 to turn-on and/or turn-off switches included in the inverter 404 that apply the driving voltage according to and/or based on the PWM signal, etc.

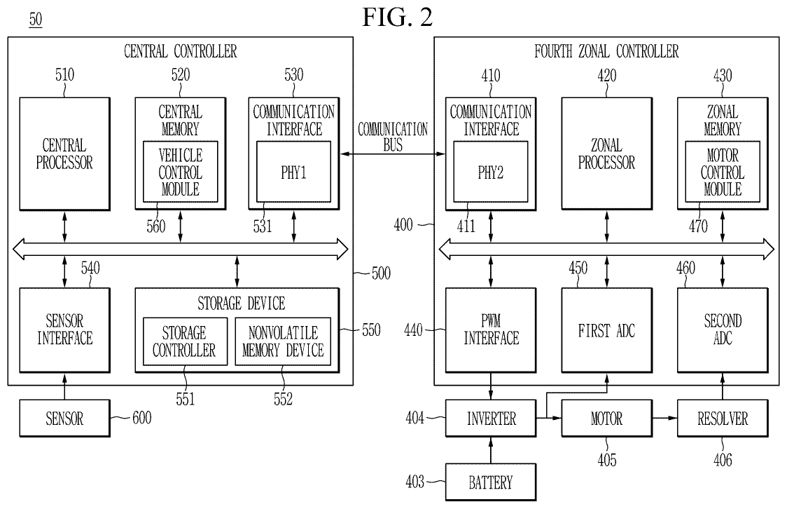

FIG. 2 is a block diagram of an example electronic system including a central controller and a zonal controller according to at least one example embodiment.

Referring to FIG. 2, the electronic system 50 may include the fourth zonal controller 400, the battery 403, the inverter 404, the motor 405, the resolver 406, the central controller 500, and/or the sensor 600, etc., but the example embodiments are not limited thereto, and for example, the electronic system 50 may include a greater or lesser number of constituent components.

In at least one example embodiment, the central controller 500 may control the fourth zonal controller 400, but is not limited thereto. The central controller 500 may include a central processor 510, a central memory 520, a communication interface (e.g., a network interface, an Ethernet interface, etc.) 530, a sensor interface 540, and/or a storage device 550, etc. According to some example embodiments, one or more of the central processor 510, the communication interface 530, the sensor interface 540, etc., may be implemented as processing circuitry. Processing circuitry may include hardware or hardware circuit including logic circuits; a hardware/software combination such as a processor executing software and/or firmware; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc., but is not limited thereto.

The central processor 510 may control the overall operation of the central controller 500. In at least one example embodiment, the central processor 510 may execute a vehicle control module 560 stored in the central memory 520, etc. In at least one example embodiment, the central processor 510 may determine a target speed corresponding to the speed at which the vehicle 10 will travel based on the speed information related to the speed of the vehicle received from the sensor 600 and/or the fourth zonal controller 400, etc.

The central memory 520 may be used as a buffer memory, a cache memory, an operating memory, or the like of the central controller 500. In at least one example embodiment, the central memory 520 may store the vehicle control module 560, etc. In at least one example embodiment, the central memory 520 may be a volatile memory device and/or non-volatile memory device. For example, the central memory 520 may be a random-access memory (RAM) and/or read-only memory (ROM), etc.

In at least one example embodiment, when the central memory 520 is a volatile memory device, the vehicle control module 560 may be stored in a non-volatile memory device 552 of the storage device 550, and the central memory 520 may receive and store the computer readable instructions corresponding to and/or associated with the vehicle control module 560 read from the non-volatile memory device 552.

In at least one example embodiment, when the central memory 520 is a non-volatile memory device, the vehicle control module 560 may be stored in the central memory 520 in the form of firmware, but is not limited thereto.

The communication interface 530 may communicate data with the fourth zonal controller 400 through at least one communication bus and/or network, such as an Ethernet network, etc., but the example embodiments are not limited thereto and other communication interfaces and/or protocols may be implemented. In at least one example embodiment, the communication interface 530 may include a first physical layer (PHY) interface 531 configured to transmit and/or receive data over the communication bus (and/or a first PHY of the communication bus, etc.) to one or more other components of the vehicle, etc.

In at least one example embodiment, the first physical layer interface 531 may receive the target speed information from the central processor 510, and may provide the target speed information to the fourth zonal controller 400. In at least one example embodiment, the first physical layer interface 531 may receive information on a rotation speed of the motor from the fourth zonal controller 400, and may provide the information on the rotation speed of the motor to the central processor 510, etc.

The sensor interface 540 may receive the travel speed information, the speed change information, and/or the gear information from the sensor 600, and may provide the travel speed information, the speed change information, and/or gear information to the central processor 510, etc.

The storage device 550 may operate under the control of the central processor 510, but is not limited thereto. The storage device 550 may include a storage controller 551 and the non-volatile memory device 552, etc.

The non-volatile memory device 552 may store data. The non-volatile memory device 552 may operate in response to the control of the storage controller 551, etc. In at least one example embodiment, the non-volatile memory device 552 may be a NAND flash memory, but is not limited thereto.

The non-volatile memory device 552 may receive at least one command and/or address from the storage controller 551, and may perform a memory operation indicated by the command with respect to a region selected by and/or indicated by the corresponding address. The non-volatile memory device 552 may perform a program operation (e.g., write operation, etc.) for storing data in a region selected by the address, a read operation for reading data, and/or an erase operation for erasing data, etc.

The storage controller 551 may control overall operation of the storage device 550.

In at least one example embodiment, the fourth zonal controller 400 may control operations performed in the fourth zone Z4 among the first to fourth zones Z1 to Z4 of the vehicle 10, but is not limited thereto, and for example, may control operations performed in two or more zones, etc. The fourth zonal controller 400 may control the motor 405 configured to drive the vehicle 10, but the example embodiments are not limited thereto.

In at least one example embodiment, the fourth zonal controller 400 may include a communication interface 410, a zonal processor 420, a zonal memory 430, a pulse-width modulation (PWM) interface 440, first analog-to-digital converter (ADC) 450, and/or a second ADC 460, etc. According to some example embodiments, one or more of the communication interface 410, the zonal processor 420, the zonal memory 430, the PWM interface 440, the first ADC 450, and/or the second ADC 460, etc., may be implemented as processing circuitry. Processing circuitry may include hardware or hardware circuit including logic circuits; a hardware/software combination such as a processor executing software and/or firmware; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc., but is not limited thereto.

The communication interface 410 may communicate data with the central controller 500 through at least one communication bus, such as an Ethernet bus and/or network, but the example embodiments are not limited thereto, and for example, other communication protocols and/or interfaces may be implemented. In at least one example embodiment, the communication interface 410 may include an interface for a second physical layer interface 411 (e.g., second PHY interface, etc.) configured to transmit and/or receive data over a second PHY of the communication bus to one or more other components of the vehicle, etc. According to some example embodiments, the first PHY and the second PHY may be separate physical layers of the communication bus, or may be combined and/or the same physical layer of the communication bus, but the example embodiments are not limited thereto.

In at least one example embodiment, the second physical layer interface 411 may receive the target speed information from the central controller 500, and may provide the target speed information to the zonal processor 420, etc. In at least one example embodiment, the second physical layer interface 411 may receive the information on the rotation speed of the motor from the zonal processor 420, and may provide the information on the rotation speed of the motor to the central controller 500.

The zonal processor 420 may control overall operation of the fourth zonal controller 400, but is not limited thereto. In at least one example embodiment, the zonal processor 420 may execute a motor control module 470 stored in the zonal memory 430. In at least one example embodiment, the zonal processor 420 may adjust the driving voltage applied to the motor 405 based on the target speed information received from the central controller 500 and/or information on the driving current corresponding to the driving voltage applied to the motor 405, etc.

The zonal memory 430 may be used as a buffer memory, a cache memory, an operating memory, or the like, of the fourth zonal controller 400. In at least one example embodiment, the zonal memory 430 may store the motor control module 470. In at least one example embodiment, the zonal memory 430 may be a volatile memory device and/or non-volatile memory device. For example, the zonal memory 430 may be a random-access memory (RAM) and/or read-only memory (ROM).

In at least one example embodiment, when a zonal memory 430 is a volatile memory device, computer readable instructions corresponding to and/or associated with the motor control module 470 may be stored in the non-volatile memory device 552 of the storage device 550, and the zonal memory 430 may receive and/or store the motor control module 470 from the non-volatile memory device 552, etc.

In at least one example embodiment, when the zonal memory 430 is a non-volatile memory device, computer readable instructions corresponding to and/or associated with the motor control module 470 may be stored in the zonal memory 430, in the form of firmware, etc.

A PWM interface 440 may generate the PWM signal for controlling the width of the driving voltage to be applied to and/or used to control the motor, and may provide the PWM signal to the inverter 404. Switches included in the inverter 404 may be turned-on and/or turned-off according to the PWM signal. The PWM interface 440 may generate the PWM signal according to the control of the zonal processor 420.

A first ADC 450 may receive the information on the driving current corresponding to the driving voltage to be applied to the motor 405. The first ADC 450 may convert the information on the driving current from an analog signal to a digital signal. The first ADC 450 may provide the information on the driving current to the zonal processor 420, but is not limited thereto.

The second ADC 460 may receive the information on a rotor position (e.g., an angle and/or displacement speed, etc.) of the motor from a resolver 460. The second ADC 460 may convert the information on the rotor position of the motor from an analog signal to a digital signal. The second ADC 460 may provide the information on the rotor position of the motor to the zonal processor 420, but is not limited thereto.

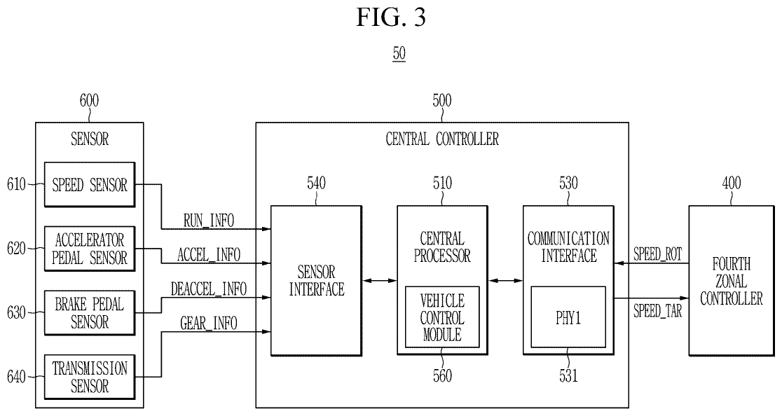

FIG. 3 is a block diagram of an example central controller according to at least one example embodiment.

Referring to FIG. 3, the electronic system 50 may include the fourth zonal controller 400, the central controller 500, and/or the sensor 600, etc., but the example embodiments are not limited thereto. The fourth zonal controller 400 may be a controller controlling the motor 405, but is not limited thereto.

The sensor 600 may include at least one of a speed sensor 610 (e.g., a speedometer, etc.), an accelerator pedal sensor 620, a brake pedal sensor 630, and/or the transmission sensor 640 (e.g., a gear selection sensor), or any combinations thereof. Additionally, in some example embodiments, the sensor 600 may further include a clutch pedal sensor, an odometer, a location sensor (e.g., GSP sensor, etc.), a compass, an altimeter, etc. Further, in some example embodiments, the sensor 600 may be safety, ADAS, and/or autonomous driving related sensors, such as radar sensors, LIDAR sensors, ultrasonic sensors, cameras (e.g., optical cameras and/or depth sensing cameras, etc.), an accelerometer, etc. The speed sensor 610 may detect the current speed of the traveling vehicle. The speed sensor 610 may generate a travel speed information RUN_INFO representing the current speed of the traveling vehicle. The speed sensor 610 may provide the travel speed information RUN_INFO to the central controller 500, but is not limited thereto.

The accelerator pedal sensor 620 may detect a level of depressing the accelerator pedal by a driver, or in other words, the accelerator pedal sensor 620 may sense and/or detect a level and/or amount of desired acceleration instructed by the driver via the accelerator pedal, etc. The accelerator pedal sensor 620 may generate an acceleration information ACCEL_INFO representing a desired change in speed to which the vehicle 10 will increase by based on the level of depressing the accelerator pedal by a driver. However, the example embodiments are not limited thereto, and for example for a vehicle with a one-pedal driving mode, the acceleration information ACCEL_INFO may further include deceleration and/or braking information based on the level of depressing the accelerator pedal by the driver, etc. The accelerator pedal sensor 620 may provide the acceleration information ACCEL_INFO to the central controller 500, but is not limited thereto.

The brake pedal sensor 630 may detect a level of depressing the brake pedal by the driver, or in other words, the brake pedal sensor 630 may sense and/or detect a desired level and/or amount of braking to be applied to the vehicle via the accelerator pedal, etc. The brake pedal sensor 630 may generate a deceleration information DEACCEL_INFO representing a desired change in speed to which the vehicle 10 will decrease based on the level of depressing the brake pedal by the driver. The brake pedal sensor 630 may provide the deceleration information DEACCEL_INFO to the central controller 500, but is not limited thereto.

The transmission sensor 640 may detect the position of the transmission (e.g., detect whether the vehicle is in Park, Drive, Reverse, Neutral, first gear, second gear, third gear, etc.), but is not limited thereto. For example, the transmission sensor 640 may detect other driving related settings of the vehicle, such as a 4×4 mode, an all-wheel drive mode, a traction control mode, a comfort mode, a sports mode, a fuel/energy savings mode, a hybrid mode, etc. The transmission sensor 640 may generate a gear information GEAR_INFO representing the position of the transmission and/or other drive related settings of the vehicle. The transmission sensor 640 may provide the gear information GEAR_INFO to the central controller 500, but is not limited thereto. According to some example embodiments, the

The central controller 500 may include the central processor 510, the communication interface 530, and/or the sensor interface 540, etc., but is not limited thereto.

The sensor interface 540 may receive vehicle operation related information, such as the travel speed information RUN_INFO, the acceleration information ACCEL_INFO, the deceleration information DEACCEL_INFO, and/or the gear information GEAR_INFO, etc., from the sensor 600, but is not limited thereto, and for example, the sensor interface 540 may receive safety related information, such as collision warning information (not shown), etc., steering warning information (not shown) indicating that the vehicle 10 has deviated from its current traffic lane, autonomous driving information (not shown) indicating autonomous driving related information (such as steering direction information, navigation information, etc.), from the sensor 600, but the example embodiments are not limited thereto. The sensor interface 540 may provide the travel speed information RUN_INFO, the acceleration information ACCEL_INFO, the deceleration information DEACCEL_INFO, and/or the gear information GEAR_INFO, etc., to the central processor 510.

The communication interface 530 may include the first physical layer interface (e.g., a first PHY layer interface, etc.) 531. The first physical layer interface 531 may receive the information on the rotation speed of the motor SPEED_ROT from the fourth zonal controller 400 over the communication bus, e.g., the first PHY of the communication bus, but is not limited thereto. The first physical layer interface 531 may provide a rotation speed information SPEED_ROT of the motor to the central processor 510, but is not limited thereto.

In at least one example embodiment, the central processor 510 may execute the vehicle control module 560. In at least one example embodiment, the vehicle control module 560 may determine the target speed corresponding to the speed at which the vehicle will travel based on the travel speed information RUN_INFO, the acceleration information ACCEL_INFO, the deceleration information DEACCEL_INFO, the gear information GEAR_INFO, and/or the rotation speed information SPEED_ROT of the motor, etc., and may generate a target speed information SPEED_TAR representing the target speed, but is not limited thereto, and for example, may also determine target steering commands corresponding to the direction the vehicle will travel based on current steering information, current location information, navigation information (e.g., desired destination information), etc. The central processor 510 may provide the target speed information SPEED_TAR to the fourth zonal controller 400 through the first physical layer interface 531, etc.

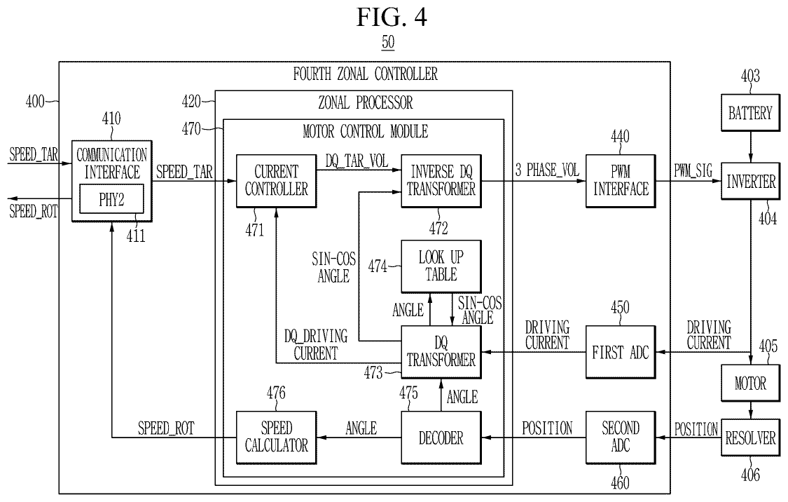

FIG. 4 is a block diagram of an example zonal controller according to at least one example embodiment.

Referring to FIG. 4, the electronic system 50 may include the fourth zonal controller 400, the battery 403, the inverter 404, the motor 405, and/or the resolver 406, etc. While the at least one example embodiment of FIG. 4 is directed towards the control of an electric motor, the example embodiments, and for example, an internal combustion engine may be controlled as well, etc.

The fourth zonal controller 400 may include the communication interface 410, the zonal processor 420, the PWM interface 440, the first ADC 450, and/or the second ADC 460, etc., but is not limited thereto.

The communication interface 410 may include the second physical layer interface 411 over the communication bus (e.g., over a second PHY layer of the communication bus, etc.), but is not limited thereto. The second physical layer interface 411 may receive the target speed information SPEED_TAR from the central controller 500. The second physical layer interface 411 may provide the target speed information SPEED_TAR to the zonal processor 420, but is not limited thereto.

The first ADC 450 may receive the information on the driving current DRIVING CURRENT corresponding to the driving voltage applied to the motor 405, but is not limited thereto. The first ADC 450 may convert the information on the driving current DRIVING CURRENT from an analog signal to a digital signal, and provide it to the zonal processor 420.

The second ADC 460 may receive a rotor position information POSITION of the motor from the resolver 406, but is not limited thereto. The second ADC 460 may provide the rotor position information POSITION of the motor to the zonal processor 420.

In at least one example embodiment, the zonal processor 420 may execute the motor control module 470, or more specifically, the computer readable instructions associated with and/or corresponding to the motor control module, etc. When the zonal processor 420 executes the computer readable instructions of the motor control module 470, the zonal processor 420 may generate a 3-phase voltage information 3 PHASE_VOL used for generating the PWM signal based on the target speed information SPEED_TAR, the information on the driving current DRIVING CURRENT, and/or the rotor position information POSITION of the motor, etc., but the example embodiments are not limited thereto, and for example, the voltage information may be a single-phase voltage information. Additionally, the zonal processor 420 may execute the computer readable instructions of the motor control module 470 to generate the rotation speed information SPEED_ROT of the motor based on the rotor position information POSITION of the motor, and may provide the rotation speed information SPEED_ROT of the motor to the central controller 500 through the second physical layer interface 411, etc., but is not limited thereto.

In at least one example embodiment, the motor control module 470 may include a current controller 471, inverse direct-quadrature (DQ) converter 472, a DQ converter 473, a lookup table 474, a decoder 475, and/or a speed calculator 476, etc., but the example embodiments are not limited thereto, and for example, the decoder 475 may be omitted and the rotor information generated by a resolver may be used, etc. According to some example embodiments, one or more of the motor control module 470, the current controller 471, the inverse direct-quadrature (DQ) converter 472, the DQ converter 473, the lookup table 474, the decoder 475, and/or the speed calculator 476, etc., may be implemented as processing circuitry. Processing circuitry may include hardware or hardware circuit including logic circuits; a hardware/software combination such as a processor executing software and/or firmware; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc., but is not limited thereto.

A decoder 475 may receive the rotor position information POSITION of the motor from the second ADC 460, but is not limited thereto. The decoder 475 may identify a rotor angle of the motor based on the rotor position information POSITION of motor. The decoder 475 may generate rotor angular information ANGLE based on the rotor position information POSITION of motor, etc. The decoder 475 may provide the rotor angular information ANGLE to the DQ converter 473 and/or the speed calculator 476, etc.

The speed calculator 476 may calculate the rotation speed of the motor based on the rotor angular information ANGLE. The speed calculator 476 may generate the rotation speed information SPEED_ROT of the motor based on the rotor angular information ANGLE. The speed calculator 476 may provide the rotation speed information SPEED_ROT of the motor to the central controller 500 through the communication interface 410, etc.

The DQ converter 473 may receive the information on the driving current DRIVING CURRENT from the first ADC 450. In at least one example embodiment, the information on the driving current DRIVING CURRENT may be information representing a value of the driving current flowing between the inverter 404 and the motor 405 as the driving voltage is applied to the motor 405. In at least one example embodiment, the driving current may be a 3-phase current, but is not limited thereto, and for example, may be a single-phase current, etc.

In at least one example embodiment, the DQ converter 473 may receive the rotor angular information ANGLE from the decoder 475, and may receive a sine-cosine angular information SIN-COS ANGLE representing sine value and cosine value corresponding to the rotor angle from the lookup table 474. The DQ converter 473 may provide the sine-cosine angular information SIN-COS ANGLE to an inverse DQ converter 472.

In at least one example embodiment, the DQ converter 473 may perform a DQ conversion that converts the driving current to a DQ-axis driving current based on the information on the driving current DRIVING CURRENT and the sine-cosine angular information SIN-COS ANGLE.

In at least one example embodiment, the DQ conversion may include a Clarke conversion that converts the value of the driving current to a value of an alpha-beta axis current of a stationary reference frame and a Park conversion that converts the value of the alpha-beta axis current to a value of a DQ-axis current of a rotor reference frame, but the example embodiments are not limited thereto.

In at least one example embodiment, the DQ converter 473 may convert the value of the driving current to the DQ-axis the value of the driving current, and may generate a DQ-axis driving current information DQ_DRIVING CURRENT representing the DQ-axis the value of the driving current. The DQ converter 473 may provide the DQ-axis driving current information DQ_DRIVING CURRENT to the current controller 471.

The current controller 471 may receive the target speed information SPEED_TAR and the DQ-axis driving current information DQ_DRIVING CURRENT. In at least one example embodiment, the target speed information SPEED_TAR may be information representing the target speed at which the vehicle 10 will travel as a value of a target current. The current controller 471 may determine a DQ-axis target voltage based on the result of comparison between the DQ-axis driving current and the target current corresponding to the target speed. In at least one example embodiment, the current controller 471 may include Proportional-Integral Controller.

The current controller 471 may generate DQ-axis target voltage information DQ_TAR_VOL representing the value of the DQ-axis target voltage based on the target speed information SPEED_TAR and the DQ-axis driving current information DQ_DRIVING CURRENT. The current controller 471 may provide the DQ-axis target voltage information DQ_TAR_VOL to the inverse DQ converter 472.

In at least one example embodiment, the inverse DQ converter 472 may perform an inverse DQ conversion that converts the DQ-axis target voltage to a 3-phase voltage based on the DQ-axis target voltage information DQ_TAR_VOL and the sine-cosine angular information SIN-COS ANGLE. In at least one example embodiment, the inverse DQ conversion may be an operation to convert the value of the DQ-axis target voltage to a value of 3-phase voltage.

In at least one example embodiment, the inverse DQ converter 472 may convert the value of the DQ-axis target voltage to a value of 3-phase voltage, and may generate the 3-phase voltage information 3 PHASE_VOL representing the value of the 3-phase voltage. The inverse DQ converter 472 may provide the 3-phase voltage information 3 PHASE_VOL to the PWM interface 440.

The PWM interface 440 may generate a PWM signal PWM_SIG based on the 3-phase voltage information 3 PHASE_VOL received from the inverse DQ converter 472. The PWM signal PWM_SIG may be a signal to control the width of the driving voltage applied to the motor 405. The PWM interface 440 may provide the PWM signal PWM_SIG to the inverter 404. Switches included in the inverter 404 may be turned-on and/or turned-off according to the PWM signal PWM_SIG.

According to the electronic system 50 included in the vehicle 10 according to at least one of the example embodiments of the inventive concepts, a central controller controlling a plurality of zonal controllers may determine the target speed corresponding to the desired speed at which the vehicle 10 will travel, and one zonal controller controlling the operation performed in one zone among a plurality of zones may control at least one motor configured to drive the vehicle 10, thereby improving the performance of controlling the vehicle in the longitudinal direction.

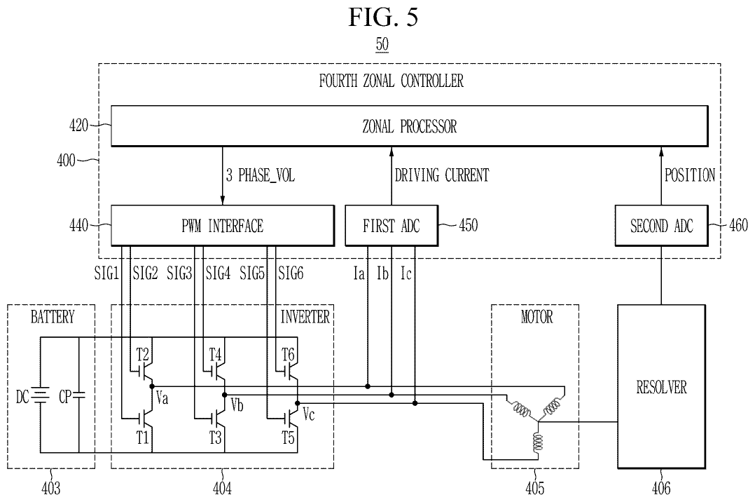

FIG. 5 is a diagram of an example inverter, motor, and zonal controller according to at least one example embodiment.

Referring to FIG. 5, the electronic system 50 may include the fourth zonal controller 400, the battery 403, the inverter 404, the motor 405, and/or the resolver 406, etc., but is not limited thereto.

The fourth zonal controller 400 may include the zonal processor 420, the PWM interface 440, the first ADC 450, and/or the second ADC 460, etc., but is not limited thereto.

The battery 403 may include a power DC (e.g., DC power supply, DC power source, etc.) and/or a capacitor CP, etc. The battery 403 may be connected to an inverter 405. The power DC may supply a DC power. The capacitor CP may store electrical energy. The capacitor CP may output DC power supplied by the power DC.

In at least one example embodiment, the zonal processor 420 may generate the 3-phase voltage information 3 PHASE_VOL based on the target speed information received from the central controller 500, the information on the driving current DRIVING CURRENT received through the first ADC 450, and/or the rotor position information POSITION of the motor received through the second ADC 460, etc., but is not limited thereto. The zonal processor 420 may provide the 3-phase voltage information 3 PHASE_VOL to the PWM interface 440.

The PWM interface 440 may generate a PWM signal based on the 3-phase voltage information 3 PHASE_VOL. The PWM signal may include a plurality of signals, e.g., first to sixth signals SIG1 to SIG6, but is not limited thereto, and for example, may include a greater or lesser number of signals, etc. The PWM interface 440 may apply the first to sixth signals SIG1 to SIG6 to the inverter 404 based on the 3-phase voltage information 3 PHASE_VOL, to for example, instruct and/or control the inverter 404 to turn-on and/or turn-off first to sixth switches T1 to T6 included in the inverter 404, etc.

The inverter 404 may apply the driving voltage converted from the DC power supplied from the battery 403 to the motor 405. In at least one example embodiment, the driving voltage may be a 3-phase voltage, but is not limited thereto, and for example, may be a single-phase voltage, etc. 3-phase voltage may include an A-phase voltage Va, a B-phase voltage Vb, and a C-phase voltage Vc.

In at least one example embodiment, the inverter 404 may include a first switch T1, a second switch T2, a third switch T3, a fourth switch T4, a fifth switch T5, and/or a sixth switch T6, etc., but is not limited thereto.

In at least one example embodiment, the first switch T1 and the second switch T2 may be turned-on and/or turned-off according to and/or based on a first signal SIG1 and/or a second signal SIG2 received from the PWM interface 440, etc. The width of the A-phase voltage Va applied to the motor 405 may be changed according to and/or corresponding to the time at which the first switch T1 and/or the second switch T2 are to be turned-on and/or turned-off. The time at which the first switch T1 and/or the second switch T2 are turned-on and/or turned-off may be changed according to the first signal SIG1 and/or the second signal SIG2, etc. In other words, the zonal processor 420 may control the first switch T1 and/or second switch T2 using at least one control signal (e.g., PWM signal, etc.).

In at least one example embodiment, the third switch T3 and/or the fourth switch T4 may be turned-on and/or turned-off according to a third signal SIG3 and/or a fourth signal SIG4 received from the PWM interface 440, etc. The width of a B-phase voltage Vb applied to the motor 405 may be changed according to and/or corresponding to the time at which the third switch T3 and/or the fourth switch T4 are to be turned-on and/or turned-off. The time at which the third switch T3 and/or the fourth switch T4 are turned-on and/or turned-off may be changed according to and/or based on the third signal SIG3 and/or the fourth signal SIG4, etc. In other words, the zonal processor 420 may control the third switch T3 and/or the fourth switch T4 using at least one control signal (e.g., PWM signal, etc.).

In at least one example embodiment, the fifth switch T5 and/or the sixth switch T6 may be turned-on and/or turned-off according to a fifth signal SIG5 and/or a sixth signal SIG6 received from the PWM interface 440. The width of the C-phase voltage Vc applied to the motor 405 may be changed according to and/or corresponding to the time at which the fifth switch T5 and/or the sixth switch T6 are to be turned-on and/or turned-off, etc. The time at which the fifth switch T5 and/or the sixth switch T6 are turned-on and/or turned-off may be changed according to and/or based on the fifth signal SIG5 and the sixth signal SIG6. In other words, the zonal processor 420 may control the fifth switch T5 and/or the sixth switch T6 using at least one control signal (e.g., PWM signal, etc.).

In at least one example embodiment, the PWM interface 440 may adjust the time at which the plurality of switches, e.g., the first to sixth switches T1 to T6, etc., are turned-on and/or turned-off based on the plurality of signals, e.g., the first to sixth signals SIG1 to SIG6, etc., and the widths of the A-phase voltage Va, B-phase voltage Vb, and/or the C-phase voltage Vc applied to the motor 405 may be adjusted according to and/or corresponding to the time at which the first to sixth switches T1 to T6 are to be turned-on and/or turned-off, etc.

The first ADC 450 may receive the driving current flowing between the inverter 404 and the motor 405 as the A-phase voltage Va, B-phase voltage Vb, and the C-phase voltage Vc are applied to the motor 405. In at least one example embodiment, the driving current may be a 3-phase current, but is not limited thereto, and for example, may be a single-phase current. 3-phase current may include an A-phase current Ia, a B-phase current Ib, and a C-phase current Ic. The first ADC 450 may provide the information on the driving current DRIVING CURRENT representing values of the A-phase current Ia, the B-phase current Ib, and the C-phase current Ic to the zonal processor 420, etc.

The resolver 406 may detect the rotor position of the motor. The resolver 406 may provide the rotor position information POSITION representing the rotor position of the motor to the zonal processor 420 through the second ADC 460, but is not limited thereto.

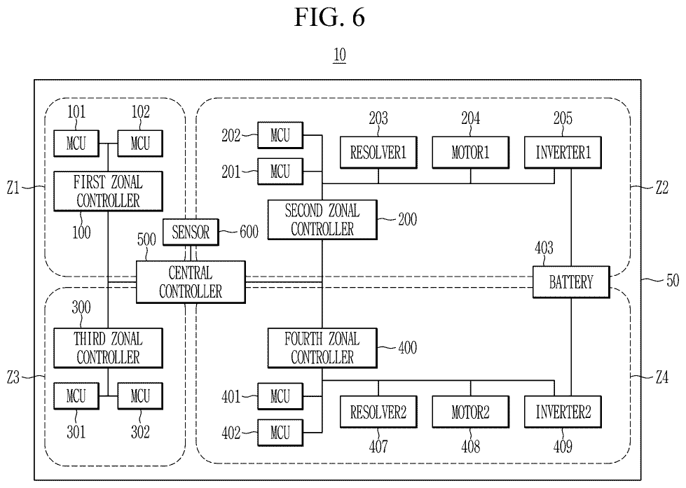

FIG. 6 is a block diagram of example zonal controllers for controlling a plurality of motors according to at least one example embodiment.

Referring to FIG. 6, the vehicle 10 may include the electronic system 50, but is not limited thereto. The vehicle 10 may include a plurality of zones, such as the first zone Z1, the second zone Z2, the third zone Z3, and/or the fourth zone Z4, etc., but is not limited thereto, and for example, may include a greater or lesser number of zones, etc. In at least one example embodiment, the first zonal controller 100 may control the first zone Z1, the second zonal controller 200 may control the second zone Z2, the third zonal controller 300 may control the third zone Z3, and/or the fourth zonal controller 400 may control the fourth zone Z4, etc.

In at least one example embodiment, the second zonal controller 200 may control at least one first motor 204, etc. In at least one example embodiment, the first motor 204 may be at least one motor to drive at least one wheel located in the front of the vehicle (e.g., a wheel located in the first zone of the vehicle, etc.), but is not limited thereto. In at least one example embodiment, the fourth zonal controller 400 may control at least one second motor 408. In at least one example embodiment, the second motor 408 may be at least one motor configured to drive at least one wheel located in the rear of the vehicle (e.g., a wheel located in the second zone of the vehicle, etc.), but is not limited thereto.

In at least one example embodiment, as described in connection with FIG. 2, the fourth zonal controller 400 may include the communication interface 410, the zonal processor 420, the zonal memory 430, the PWM interface 440, the first ADC 450, and/or the second ADC 460, etc.

In at least one example embodiment, the second zonal controller 200 may be implemented in the same way as the fourth zonal controller 400, but is not limited thereto. In at least one example embodiment, the second zonal controller 200 may include at least one communication interface (e.g., Ethernet interface, etc.) configured to receive the target speed information from the central controller 500, a first ADC configured to receive first information on the driving current corresponding to a first driving voltage applied to the first motor 204, a second ADC configured to receive rotor position information of the first motor from a first resolver 203, a zonal processor configured to generate the 3-phase voltage information based on the target speed information, the first information on the driving current, and/or the rotor position information of the first motor, etc., a zonal memory, and/or a PWM interface configured to generate the PWM signal for turning-on and/or turning-off switches included in a first inverter 205 based on the 3-phase voltage information, etc.

In at least one example embodiment, the first inverter 205 may convert voltage of the battery 403 to the first driving voltage, and may apply the first driving voltage to the at least one first motor 204. The at least one first motor 204 may drive at least one wheel connected to the at least one first motor 204 according to and/or based on the first driving voltage. A second inverter 409 may convert voltage of the battery 403 to a second driving voltage, and may apply the second driving voltage to the at least one second motor 408. The at least one second motor 408 may drive at least one wheel connected to the at least one second motor 408 according to the second driving voltage. While FIG. 5 illustrates two motors in the vehicle, the example embodiments are not limited thereto, and for example, the vehicle may include a single motor or three or more motors for driving the wheels of the vehicle, etc.

In at least one example embodiment, the first resolver 203 may detect a rotor position of the first motor 204 and a second resolver 409 may detect a rotor position of the second motor 408, but the example embodiments are not limited thereto, and there may be a greater or lesser number of resolvers and/or motors, etc.

In at least one example embodiment, the central controller 500 may receive the travel speed information representing a speed of the vehicle, the speed change information representing the speed to which the vehicle will increase or decrease, and/or the gear information representing the position of the transmission from the sensor 600, etc. The central controller 500 may receive first rotation speed information representing a speed at which the first motor 204 rotates from the second zonal controller 200, etc. The central controller 500 may receive second rotation speed information representing a speed at which the second motor 408 rotates from the fourth zonal controller 400, etc.

In at least one example embodiment, the central controller 500 may determine the target speed corresponding to the speed at which the vehicle will travel based on the travel speed information, the speed change information, the gear information, first rotation speed information, and/or second rotation speed information, etc., but is not limited thereto. The central controller 500 may provide the target speed information representing the target speed to the second zonal controller 200 and/or the fourth zonal controller 400, etc.

In at least one example embodiment, the second zonal controller 200 may generate a first PWM signal that may adjust a width of the first driving voltage based on the target speed information, information on the rotor position of the first motor, and/or the first information on the driving current corresponding to the first driving voltage applied to the first motor 204, etc., but is not limited thereto. The second zonal controller 200 may turn-on and/or turn-off switches included in the first inverter 205 based on the first PWM signal. The first motor 204 may drive the wheel connected to the first motor 204 according to and/or based on the first driving voltage whose width is adjusted.

In at least one example embodiment, the fourth zonal controller 400 may generate a second PWM signal that may adjust a width of the second driving voltage based on the target speed information, information on the rotor position of the second motor, and/or second information on the driving current corresponding to the second driving voltage applied to the second motor 408, etc., but is not limited thereto. The fourth zonal controller 400 may turn-on and/or turn-off switches included in the second inverter 409 based on the second PWM signal. The second motor 408 may drive the wheel connected to the second motor 408 according to and/or based on the second driving voltage whose width is adjusted.

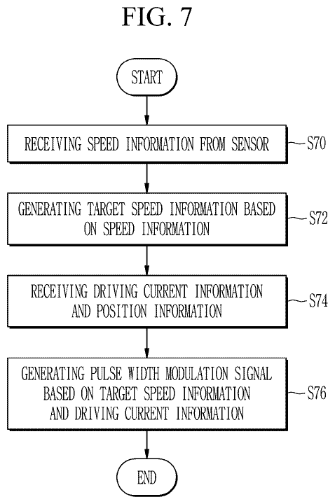

FIG. 7 is a flowchart illustrating an example method of operating an electronic system according to at least one example embodiment.

Referring to FIG. 7, at operation S70, the central controller 500 included in the electronic system 50 may receive the speed information from the sensor. The speed information may include the travel speed information representing the speed of the travel vehicle, acceleration information representing a speed to which the vehicle will increase, the speed change information representing a speed to which the vehicle will decrease, and/or the gear information representing the position of the transmission, etc., but the example embodiments are not limited thereto. In at least one example embodiment, the central controller 500 may receive the rotation speed information representing a speed and/or revolutions per minute (RPMs) at which the at least one motor rotates from the zonal controller controlling the motor among the plurality of zonal controllers included in the electronic system 50, etc., but is not limited thereto.

At operation S72, the central controller 500 may generate the target speed information representing the desired speed at which the vehicle will travel based on the speed information. The central controller 500 may provide the target speed information to the zonal controller controlling the at least one motor among the plurality of zonal controllers.

At operation S74, the zonal controller controlling the at least one motor may receive the driving current information and/or the position information, etc., but is not limited thereto. The driving current information may be information representing the value of the driving current flowing between the inverter and the at least one motor according to the driving voltage applied to the at least one motor. The position information may be information representing the rotor position of the at least one motor.

At operation S76, the zonal controller controlling the at least one motor may generate the PWM signal based on the target speed information and/or the driving current information, etc., but is not limited thereto. The PWM signal may be at least one signal used to control the at least one motor of the vehicle by changing a width of the driving voltage applied to the at least one motor that drives the vehicle.

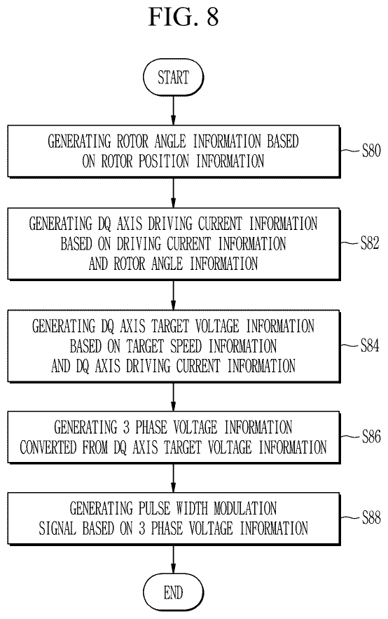

FIG. 8 is a flowchart illustrating an example method of operating a zonal controller according to at least one example embodiment.

In at least one example embodiment, FIG. 8 may correspond to operation S76 of FIG. 7. Referring to FIG. 8, at operation S80, the zonal controller controlling the at least one motor among the plurality of zonal controllers may generate the rotor angular information based on rotor position information of the at least one motor. In at least one example embodiment, the zonal controller controlling the motor may calculate the rotation speed of the motor based on the rotor angular information, and may provide the information on the rotation speed of the motor to the central controller 500.

At operation S82, the zonal controller controlling the motor may generate the DQ-axis driving current information based on the driving current information and/or the rotor angular information, etc. In at least one example embodiment, the zonal controller controlling the at least one motor may perform the DQ conversion that converts the value of the driving current to the DQ-axis the value of the driving current, and may generate the DQ-axis driving current information representing the value of the DQ-axis driving current.

At operation S84, the zonal controller controlling the at least one motor may generate the DQ-axis target voltage information based on target current information and/or the DQ-axis driving current information, etc. In at least one example embodiment, the zonal controller controlling the at least one motor may determine the DQ-axis target voltage based on the result of comparison between the DQ-axis driving current and the target current corresponding to the target speed, and may generate the DQ-axis target voltage information representing the value of the DQ-axis target voltage.

At operation S86, the zonal controller controlling the at least one motor may generate the 3-phase voltage information based on and/or converted from the DQ-axis target voltage information. In at least one example embodiment, the zonal controller controlling the at least one motor may perform the inverse DQ conversion that converts the DQ-axis target voltage to 3-phase voltage, and may generate the 3-phase voltage information representing the value of the 3-phase voltage.

At operation S88, the zonal controller controlling the at least one motor may generate the PWM signal based on the 3-phase voltage information. In at least one example embodiment, the zonal controller controlling the at least one motor may provide the PWM signal to the inverter that applies the driving voltage to the at least one motor, etc., but is not limited thereto.

While various example embodiments of the inventive concepts have been described in connection with several illustrations, it is to be understood that the example embodiments of the inventive concepts are not limited thereto. On the contrary, it is intended that the inventive concepts cover various modifications and equivalent arrangements included within the spirit and scope of the appended claims.

What is claimed is:

1. An electronic system, comprising:
a central controller configured to,
receive speed information related to a current speed of a vehicle,
generate a target speed information representing a speed at which the vehicle will travel based on the speed information, and
transmit the target speed information; and
a first zonal controller configured to control a first zone among a plurality of zones of the vehicle; and
a second zonal controller configured to control a second zone among the plurality of zones of the vehicle, and control at least one motor of the vehicle based on the target speed information received from the central controller,
the at least one motor configured to drive at least one wheel of the vehicle.

2. The electronic system of claim 1, wherein the second zonal controller is further configured to:
receive the target speed information through a physical layer of a communication bus.

3. The electronic system of claim 1, wherein the speed information comprises:
speed change information received from a pedal sensor; and
rotation speed information corresponding to the at least one motor.

4. The electronic system of claim 1, wherein the second zonal controller is further configured to:
control the at least one motor based on the target speed information using a pulse width modulation (PWM) signal, the controlling the at least one motor including,
an inverter connected to the at least one motor, the inverter configured to apply a driving voltage to the at least one motor based on the PWM signal.

5. The electronic system of claim 1, wherein the second zonal controller comprises:
a first analog-to-digital converter (ADC) configured to receive information on a driving current corresponding to a driving voltage applied to the at least one motor; and
a second ADC configured to receive rotor position information of a rotor included in the at least one motor.

6. The electronic system of claim 5, wherein the second zonal controller is further configured to:
generate rotation speed information corresponding to the at least one motor based on the rotor position information; and
provide the rotation speed information to the central controller through a communication bus.

7. The electronic system of claim 6, wherein the second zonal controller is further configured to:
generate angular information corresponding to the rotor based on the rotor position information; and
generate direct-quadrature (DQ)-axis driving current information based on the driving current information and the angular information of the rotor.

8. The electronic system of claim 7, wherein the second zonal controller is further configured to:
generate a DQ-axis target voltage information based on the DQ-axis driving current information and target current information corresponding to the target speed information; and
generate 3-phase voltage information based on the DQ-axis target voltage information.

9. The electronic system of claim 8, wherein the second zonal controller is further configured to:
adjust a width of a driving voltage to be applied to the at least one motor based on the 3-phase voltage information.

10. An electronic system, comprising:
an inverter configured to convert a voltage of a battery to a driving voltage;
at least one motor configured to operate based on the driving voltage;
a plurality of zonal controllers configured to control each of a plurality of zones of a vehicle; and
a central controller configured to determine target speed information based on current rotation speed information of the at least one motor and desired speed information of the vehicle housing the at least one motor, the target speed information indicating a target speed at which the vehicle will travel, and the desired speed information indicating a desired speed to which the vehicle will increase or decrease,
wherein one zonal controller for controlling one of the plurality of zones of the vehicle is configured to,
receive the target speed, and
adjust the driving voltage based on a target current corresponding to the target speed information and a driving current corresponding to the driving voltage.

11. The electronic system of claim 10, wherein the central controller is further configured to:
receive the desired speed information from a sensor configured to detect a position of a pedal; and
receive rotation speed information of the at least one motor from the zonal controller.

12. The electronic system of claim 10, wherein the one zonal controller is further configured to:
receive the target speed information from the central controller.

13. The electronic system of claim 10, wherein the one zonal controller comprises:
a first analog-to-digital converter (ADC) configured to receive information regarding the driving current; and
a second ADC configured to receive information regarding a rotor position of the at least one motor.

14. The electronic system of claim 13, wherein the one zonal controller is further configured to:
identify a rotor angle of the at least one motor based on information on the rotor position of the at least one motor; and
convert the driving current to a direct-quadrature (DQ)-axis driving current based on the identified rotor angle.

15. The electronic system of claim 14, wherein the one zonal controller is further configured to:
determine rotation speed information of the at least one motor based on the identified rotor angle; and
provide the rotation speed information of the at least one motor to the central controller.

16. The electronic system of claim 14, wherein the one zonal controller is further configured to:
determine a DQ-axis target voltage based on the target current and the DQ-axis driving current; and
convert the DQ-axis target voltage to 3-phase voltage based on the identified rotor angle.

17. The electronic system of claim 16, wherein the one zonal controller is further configured to:
control a width of the driving voltage based on information on the 3-phase voltage.

18. A vehicle, comprising:
a first motor and a second motor each configured to drive at least one first wheel and at least one second wheel, respectively;
a central controller configured to generate target speed information and speed change information of the vehicle, the target speed information representing a speed at which the vehicle will travel based on rotation speed information of the first motor and the second motor;
a first zonal controller configured to control a first zone among a plurality of zones of the vehicle, and control a first driving voltage applied to the first motor based on the target speed information; and
a second zonal controller configured to control a second zone among a plurality of zones of the vehicle, and control a second driving voltage applied to the second motor based on the target speed information.

19. The vehicle of claim 18, the vehicle further comprises:
a communication bus; and wherein
the central controller is further configured to receive the rotation speed information through the communication bus; and
the first zonal controller and the second zonal controller are each configured to receive the target speed information through the communication bus.

20. The vehicle of claim 18, wherein
the central controller is further configured to determine a target current corresponding to the target speed information based on the rotation speed information of the first motor and the second motor and the speed change information of the vehicle; and
the first zonal controller and the second zonal controller each further configured to,
receive rotor position information of the first motor and the second motor, respectively, and
generate the rotation speed information based on the respective rotor position information.
